(19) United States
(12) Patent Application Publication
(10) Pub. No.: US 2026/0250205 A1
(43) Pub. Date: Aug. 27, 2026

(54) ALUMINUM NITRIDE SINTERED BODY

(71) Applicant: NGK Corporation, Nagoya-shi (JP)

(72) Inventors: Keita YAMANA, Nagoya-shi (JP); Kazuhiro NOBORI, Handa-shi (JP); Keiichi NAKAMURA, Handa-shi (JP); Koyu MURAKAMI, Nagoya-shi (JP); Yuki SHIRAKI, Nagoya-shi (JP)

(73) Assignee: NGK Corporation, Nagoya-shi (JP)

(21) Appl. No.: 19/654,729

(22) Filed: Apr. 22, 2026

Related U.S. Application Data
(63) Continuation of application No. PCT/JP2025/022591, filed on Jun. 24, 2025.

(30) Foreign Application Priority Data
Oct. 8, 2024 (JP) 2024-176431

(51) Int. Cl. C04B 35/581; H10P 72/72

(52) U.S. Cl. CPC C04B 35/581; H10P 72/722; C04B 2235/3869; C04B 2235/786; C04B 2235/85; C04B 2235/96

(57) ABSTRACT

An aluminum nitride sintered body includes a plurality of crystal grains and a grain boundary. Each of the plurality of crystal grains contains aluminum nitride. The grain boundary is positioned between adjacent crystal grains among the plurality of crystal grains. The average grain size of the plurality of crystal grains is from 1.5 μm to 3.0 μm. The grain boundary includes a portion in which an aluminum oxynitride containing calcium is present in an isolated state. In the aluminum nitride sintered body, the content ratio of metal elements excluding aluminum is more than 30 ppm and 300 ppm or less.

### CROSS-REFERENCE TO RELATED APPLICATIONS

This application is a continuation under 35 U.S.C. 120 of International Application PCT/JP2025/022591 having the International Filing Date of Jun. 24, 2025 and having the benefit of the earlier filing date of Japanese Application No. 2024-176431 filed on Oct. 8, 2024. Each of the identified applications is fully incorporated herein by reference.

### BACKGROUND OF THE INVENTION

### 1. Field of the Invention

The present disclosure relates to an aluminum nitride sintered body.

### 2. Description of the Related Art

It has heretofore been known that various treatments are performed on a silicon wafer supported by a susceptor in the manufacture of a semiconductor device such as an integrated circuit. As a material for forming such susceptor, there is a proposal of, for example, an aluminum nitride sintered body, in which the contents of metal elements excluding aluminum are each 100 ppm or less, and which exhibits black coloration with a lightness of N4 or less as specified in JIS Z 8721 (see Patent Literature 1).

### CITATION LIST

### Patent Literature

[PTL 1] JP 2883207 B2

### SUMMARY OF THE INVENTION

An electrostatic chuck capable of adsorbing a silicon wafer may be formed by arranging an electrode on such susceptor. Examples of the adsorption principle of the electrostatic chuck include Coulomb force and Johnsen-Rahbek force (hereinafter referred to as “JR force”).

In an electrostatic chuck utilizing Coulomb force (hereinafter referred to as “Coulomb electrostatic chuck”), a silicon wafer is adsorbed by applying a voltage to an electrode to positively or negatively charge the electrode, and polarizing a dielectric layer of the electrostatic chuck.

In an electrostatic chuck utilizing JR force (hereinafter referred to as “JR electrostatic chuck”), a silicon wafer is adsorbed by generating a minute leakage current between the silicon wafer and an electrode when a voltage is applied to the electrode.

In recent years, a semiconductor device has been increasingly miniaturized and/or highly integrated. In the manufacture of the semiconductor device, a silicon wafer is treated in various temperature ranges. An electrostatic chuck is required to stably adsorb a silicon wafer in the temperature range of, for example, 250° C. or more in some cases.

However, the volume resistivity of an aluminum nitride sintered body decreases with an increase in temperature. Accordingly, when the Coulomb electrostatic chuck is used in the temperature range of 250° C. or more, there is a risk in that Coulomb force cannot be stably exhibited. Accordingly, the JR electrostatic chuck is typically used in the temperature range of 250° C. or more.

In addition, in the manufacture of the semiconductor device, it has been desired to reduce particles adhering to the silicon wafer. A cause of the particles is, for example, detachment of crystal grains (hereinafter referred to as “grain detachment”) from an aluminum nitride sintered body for forming a susceptor.

In view of the foregoing, it is investigated to suppress the grain detachment by reducing the grain sizes of crystal grains in an aluminum nitride sintered body. However, when the grain sizes of the crystal grains are reduced, the proportion of grain boundaries in the aluminum nitride sintered body increases, and hence the volume resistivity of the aluminum nitride sintered body may be increased.

When such aluminum nitride sintered body is applied to the JR electrostatic chuck, depending on the temperature range, it may become difficult to generate an appropriate leakage current between the silicon wafer and the electrode, and there is a risk in that JR force cannot be stably exhibited.

A primary object of the present disclosure is to provide an aluminum nitride sintered body that can suppress grain detachment and can be suitably applied to an electrostatic chuck utilizing JR force.

[1] An aluminum nitride sintered body according to one embodiment of the present disclosure includes a plurality of crystal grains and a grain boundary. Each of the plurality of crystal grains contains aluminum nitride. The grain boundary is positioned between adjacent crystal grains among the plurality of crystal grains. An average grain size of the plurality of crystal grains is from 1.5 μm to 3.0 μm. The grain boundary includes a portion in which an aluminum oxynitride containing calcium is present in an isolated state. In the aluminum nitride sintered body, a content ratio of metal elements excluding aluminum is more than 30 ppm and 300 ppm or less.

[2] In the aluminum nitride sintered body according to the above-mentioned item [1], the content ratio of the metal elements excluding aluminum may be more than 100 ppm.

[3] In the aluminum nitride sintered body according to the above-mentioned item [1] or [2], a standard deviation of the average grain size of the plurality of crystal grains may be 1.0 μm or less.

[4] In the aluminum nitride sintered body according to any one of the above-mentioned items [1] to [3], a volume resistivity of the aluminum nitride sintered body measured at 300° C. by applying a voltage of +500 V may be from 5.0×10⁹ Ω·cm to 1.0×10¹⁰ Ω·cm.

[5] The aluminum nitride sintered body according to any one of the above-mentioned items [1] to [4] may have a bending strength of 300 MPa or more.

According to the embodiment of the present disclosure, the aluminum nitride sintered body that can suppress grain detachment and can be suitably applied to an electrostatic chuck utilizing JR force can be achieved.

### BRIEF DESCRIPTION OF THE DRAWINGS

FIG. 1 is a schematic configuration view of an aluminum nitride sintered body according to one embodiment of the present disclosure.

FIG. 2 is a schematic cross-sectional view of an electrostatic chuck including the aluminum nitride sintered body of FIG. 1.

FIG. 3 is a mapping image of aluminum (Al) in an aluminum nitride sintered body of Example.

FIG. 4 is a mapping image of calcium (Ca) in the aluminum nitride sintered body of Example.

FIG. 5 is a mapping image of oxygen (O) in the aluminum nitride sintered body of Example.

FIG. 6 is a mapping image of nitrogen (N) in the aluminum nitride sintered body of Example.

FIG. 7 is a mapping image of aluminum (Al) in an aluminum nitride sintered body of Comparative Example.

FIG. 8 is a mapping image of calcium (Ca) in the aluminum nitride sintered body of Comparative Example.

FIG. 9 is a mapping image of oxygen (O) in the aluminum nitride sintered body of Comparative Example.

FIG. 10 is a mapping image of nitrogen (N) in the aluminum nitride sintered body of Comparative Example.

### DESCRIPTION OF THE EMBODIMENTS

Embodiments of the present disclosure are described below. However, the present disclosure is not limited to these embodiments. In addition, for clearer illustration, some widths, thicknesses, shapes, and the like of respective portions may be schematically illustrated in the drawings in comparison to the embodiments. However, the widths, the thicknesses, the shapes, and the like are each merely an example, and do not limit the interpretation of the present disclosure.

### A. Overview of Aluminum Nitride Sintered Body

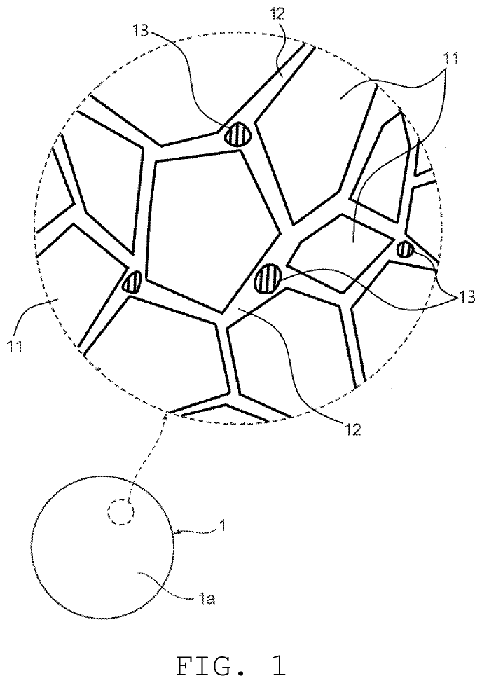

FIG. 1 is a schematic configuration view of an aluminum nitride sintered body according to one embodiment of the present disclosure.

In one embodiment, an aluminum nitride sintered body 1 includes a plurality of crystal grains 11 and a grain boundary 12. The aluminum nitride sintered body is hereinafter sometimes referred to as “AlN sintered body.”

The AlN sintered body 1 typically has a polycrystalline structure including the plurality of crystal grains 11. Among the plurality of crystal grains 11, adjacent crystal grains 11 are bonded to each other, and the grain boundary 12 is formed therebetween. Each of the plurality of crystal grains 11 contains aluminum nitride (AlN). The average grain size of the plurality of crystal grains 11 is from 1.5 μm to 3.0 μm.

The grain boundary 12 is positioned between the adjacent crystal grains 11 among the plurality of crystal grains 11. The grain boundary 12 is continuous in a three-dimensional network. In the temperature range of 250° C. or more, the volume resistivity of the grain boundary 12 is typically smaller than the volume resistivity of each of the crystal grains 11. Accordingly, the grain boundary 12 continuous in a three-dimensional network may function as a conductive path when a voltage is applied to the AlN sintered body 1.

At the grain boundary 12, an aluminum oxynitride 13 containing calcium is present in an isolated state. In other words, the grain boundary 12 includes a portion in which the aluminum oxynitride 13 containing calcium is present in an isolated state. The chemical formula of the aluminum oxynitride is typically Al₅O₆N. The aluminum oxynitride containing calcium is hereinafter sometimes referred to as “Ca-containing AlON.”

In such AlN sintered body 1, the content ratio of metal elements excluding aluminum (Al) is more than 30 ppm and 300 ppm or less on a weight basis.

The inventors have intensively investigated appropriate control of the volume resistivity of an AlN sintered body including crystal grains having an average grain size of 3.0 μm or less in the temperature range of 250° C. or more. As a result, it has been found that when the average grain size of the crystal grains is set to be a predetermined size or more, metal elements excluding Al are each incorporated in a sufficient amount, and the Ca-containing AlON is appropriately present at the grain boundary in the AlN sintered body, the volume resistivity of the AlN sintered body in the temperature range of 250° C. or more can be adjusted within a range suitable for a JR electrostatic chuck.

More specifically, the average grain size of the crystal grains is 1.5 μm or more in the AlN sintered body, and hence a sufficient presence ratio of the grain boundary can be secured. In addition, the Ca-containing AlON is present in an isolated state at the grain boundary, and the content ratio of the metal elements excluding Al in the AlN sintered body is more than 30 ppm. Accordingly, the volume resistivity of each of the crystal grains and the grain boundary can be adjusted in a well-balanced manner, and the grain boundary can function as an appropriate conductive path for a JR electrostatic chuck.

In addition, the content ratio of the metal elements excluding Al in the AlN sintered body is 300 ppm or less, and hence the crystal grains can be prevented from excessively growing, and the average grain size of the crystal grains can be stably adjusted to be 3.0 μm or less. Accordingly, grain detachment in the AlN sintered body can be sufficiently suppressed.

As a result, an AlN sintered body that can suppress grain detachment and has a volume resistivity suitable for a JR electrostatic chuck can be achieved.

In the AlN sintered body 1, the volume resistivity measured at 300° C. by applying a voltage of +500 V (hereinafter sometimes referred to as “volume resistivity of the AlN sintered body at 300° C.”) is, for example, 1.0×10⁹ Ω·cm or more, preferably 5.0×10⁹ Ω·cm or more, more preferably 6.0×10⁹ Ω·cm or more.

When the volume resistivity of the AlN sintered body at 300° C. is equal to or more than such lower limit, in a JR electrostatic chuck to which the AlN sintered body is applied, the generation of an excessive leakage current can be suppressed, and damage to a silicon wafer by a leakage current can be suppressed.

Meanwhile, the volume resistivity of the AlN sintered body at 300° C. is, for example, 5.0×10¹¹ Ω·cm or less, preferably 1.5×10¹⁰ Ω·cm or less, more preferably 9.6×10⁹ Ω·cm or less, still more preferably 8.0×10⁹ Ω·cm or less.

When the volume resistivity of the AlN sintered body at 300° C. is equal to or less than such upper limit, in a JR electrostatic chuck to which the AlN sintered body is applied, an appropriate leakage current can be generated between a silicon wafer and an electrode, and JR force can be stably exhibited.

In the AlN sintered body 1, the volume resistivity measured at room temperature (25° C.) by applying a voltage of +500 V is, for example, from 1.0×10¹⁴ Ω·cm to 9.0×10¹⁴ Ω·cm, preferably from 2.0×10¹⁴ Ω·cm to 8.0×10¹⁴ Ω·cm.

The volume resistivity of the aluminum nitride sintered body is measured in conformity with, for example, JIS-C2141-1992.

The average grain size of the plurality of crystal grains 11 is preferably 1.8 μm or more, more preferably 2.0 μm or more.

When the average grain size of the crystal grains is equal to or more than such lower limit, each of the crystal grains and the grain boundary can be present in the AlN sintered body in a well-balanced manner, and the volume resistivity of the AlN sintered body at 300° C. can be stably adjusted within the above-mentioned ranges.

Meanwhile, the average grain size of the plurality of crystal grains 11 is preferably 2.8 μm or less, more preferably 2.6 μm or less.

When the average grain size of the crystal grains is equal to or less than such upper limit, grain detachment in the AlN sintered body can be stably suppressed, and the generation of particles can be sufficiently suppressed.

The standard deviation of the average grain size of the plurality of crystal grains 11 is, for example, 1.0 μm or less, preferably 0.5 μm or less, more preferably 0.3 μm or less. Meanwhile, the lower limit of the standard deviation of the average grain size of the plurality of crystal grains 11 is typically 0 μm.

When the standard deviation of the average grain size of the crystal grains falls within such ranges, the volume resistivity of the AlN sintered body at 300° C. can be more stably adjusted within the above-mentioned ranges.

The content ratio of metal elements excluding Al in the AlN sintered body 1 is preferably more than 100 ppm, more preferably 150 ppm or more, still more preferably 200 ppm or more.

When the content ratio of the metal elements excluding Al is equal to or more than such lower limit, the volume resistivity of the AlN sintered body at 300° C. can be still more stably adjusted within the above-mentioned ranges.

Meanwhile, the content ratio of the metal elements excluding Al in the AlN sintered body is preferably 280 ppm or less, more preferably 250 ppm or less.

When the content ratio of the metal elements excluding Al is equal to or less than such upper limit, the average grain size of the crystal grains can be stably adjusted within the above-mentioned ranges, and metal atoms excluding Al can be suitably prevented from forming particles.

The content ratios of constituent elements in the aluminum nitride sintered body are measured by inductively coupled plasma atomic emission spectroscopy (ICP-AES) in conformity with, for example, JIS-K0116.

Examples of the metal elements excluding Al include: alkaline earth metals, such as calcium (Ca) and magnesium (Mg); rare earth elements, such as yttrium (Y), cerium (Ce), and samarium (Sm); transition metals, such as zirconium (Zr), iron (Fe), and titanium (Ti); and metalloids such as silicon (Si).

The metal elements excluding Al may be used alone or in combination thereof.

In one embodiment, the metal elements excluding Al include an alkaline earth metal. Of the alkaline earth metals, Ca and Mg are preferred, and Ca is more preferred. According to such configuration, the crystal grains can be stably reduced in size, and the Ca-containing AlON can be stably present at the grain boundary.

The content ratio of the alkaline earth metal is, for example, 50 wt % or more, preferably 70 wt % or more when the total amount of the metal elements excluding Al is set to 100 wt %. Meanwhile, the content ratio of the alkaline earth metal is, for example, 95 wt % or less, preferably 90 wt % or less when the total amount of the metal elements excluding Al is set to 100 wt %.

In addition, the content ratio of the alkaline earth metal is, for example, 100 ppm or more, preferably 150 ppm or more with respect to the total amount of the AlN sintered body 1. Meanwhile, the content ratio of the alkaline earth metal is, for example, 280 ppm or less, preferably 250 ppm or less, more preferably 200 ppm or less with respect to the total amount of the AlN sintered body 1.

In one embodiment, the metal elements excluding Al include only Ca as the alkaline earth metal. When the content ratio of Ca falls within the above-mentioned ranges, the Ca-containing AlON can be prevented from forming a continuous phase, and the Ca-containing AlON can be present in an isolated state, at the grain boundary.

The metal elements excluding Al may include a transition metal that is not classified as a rare earth element in addition to the alkaline earth metal. Of such transition metals, iron (Fe) and titanium (Ti) are preferred.

The content ratio of the alkaline earth metal is, for example, from 2.0 to 8.0, preferably from 4.0 to 7.0 with respect to the content ratio of the transition metal.

The content ratio of the transition metal is, for example, 40 ppm or less, or for example, 30 ppm or less with respect to the total amount of the AlN sintered body 1. Meanwhile, the lower limit of the content ratio of the transition metal is typically 0 ppm with respect to the total amount of the AlN sintered body 1.

In addition, it is preferred that the metal elements excluding Al be substantially free of a rare earth element. According to such configuration, the generation of particles can be suppressed.

The content ratio of the rare earth element is, for example, 10 ppm or less, preferably 5 ppm or less, more preferably 3 ppm or less with respect to the total amount of the AlN sintered body 1. Meanwhile, the lower limit of the content ratio of the rare earth element is typically 0 ppm with respect to the total amount of the AlN sintered body 1.

When the content ratio of the rare earth element falls within such ranges, the crystal grains can be still more stably reduced in size.

### B. Details of Aluminum Nitride Sintered Body

Next, the aluminum nitride sintered body 1 is described in detail with reference to FIG. 1.

The AlN sintered body 1 contains AlN and the Ca-containing AlON as described above. In other words, the AlN sintered body 1 includes an AlN crystal phase and a Ca-containing AlON crystal phase.

The content ratio of AlN in the AlN sintered body 1 is, for example, 95.00 wt % or more, preferably 97.00 wt % or more. Meanwhile, the content ratio of AlN in the AlN sintered body 1 is, for example, 99.90 wt % or less, for example, 99.50 wt % or less, for example, 99.05 wt % or less, or for example, 99.00 wt % or less.

The content ratio of the Ca-containing AlON in the AlN sintered body 1 is, for example, 0.10 wt % or more, preferably 0.50 wt % or more, more preferably 0.95 wt % or more, still more preferably 1.00 wt % or more. Meanwhile, the content ratio of the Ca-containing AlON in the AlN sintered body 1 is, for example, 5.00 wt % or less, preferably 3.0 wt % or less.

The content ratio of each crystal phase in the aluminum nitride sintered body is measured by, for example, X-ray diffraction (XRD) in conformity with JIS-Z2201 and JIS-K0114.

### B-1. Crystal Grains

The AlN crystal phase is positioned within the crystal grains 11.

The AlN crystal phase typically has a wurtzite structure (hexagonal crystal system).

The AlN crystal phase may contain oxygen as a solid solution, or may contain no oxygen as a solid solution. In one embodiment, the AlN crystal phase may contain oxygen as a solid solution. When the AlN crystal phase contains oxygen as a solid solution, a crystal lattice of AlN can be suitably adjusted.

An a-axis length in the AlN crystal phase is, for example, 3.11190 Å or more, preferably 3.11200 Å or more. Meanwhile, the a-axis length in the AlN crystal phase is, for example, 3.11250 Å or less, preferably 3.11220 Å or less.

A c-axis length in the AlN crystal phase is, for example, 4.97900 Å or more, preferably 4.97910 Å or more. Meanwhile, the c-axis length in the AlN crystal phase is, for example, 4.97940 Å or less, preferably 4.97920 Å or less.

A unit cell volume in the AlN crystal phase is, for example, from 41.7600 Å³ to 41.7630 Å³, preferably from 41.7610 Å³ to 41.7620 Å³.

In the AlN crystal phase, the ratio (c/a) of the c-axis length to the a-axis length is, for example, 1.60010 or less, preferably less than 1.60000. Meanwhile, the lower limit of the ratio c/a in the AlN crystal phase is typically 1.59990.

When the AlN crystal phase has such ratio c/a, the volume resistivity of the AlN sintered body in the temperature range of 250° C. or more can be adjusted within a range suitable for a JR electrostatic chuck.

The crystal lattice is measured by, for example, X-ray diffraction (XRD).

### B-2. Grain Boundary

At least part of the Ca-containing AlON crystal phase is present in an isolated state at the grain boundary 12. At the grain boundary 12, all of the Ca-containing AlON crystal phase may be isolated, or part of the Ca-containing AlON crystal phase may be isolated and the remainder of the Ca-containing AlON crystal phase may be continuous. That is, the grain boundary 12 includes a portion in which the Ca-containing AlON crystal phase is present in an isolated state.

In one embodiment, at least part of the Ca-containing AlON crystal phase 13 is present in an isolated state at the triple point of the grain boundary 12. According to such configuration, the volume resistivity of the AlN sintered body can be still more stably adjusted within the above-mentioned ranges. The triple point of the grain boundary 12 means a portion of the grain boundary 12 surrounded by three or more crystal grains 11.

In a cross-section obtained by cutting the AlN sintered body 1, the area ratio of the Ca-containing AlON crystal phase 13 is, for example, from 20% to 70%, preferably from 30% to 65% when the total area of the grain boundary 12 is set to 100%.

In addition, in the cross-section of the AlN sintered body 1, the area ratio of the Ca-containing AlON 13 in an isolated state is, for example, from 60% to 100% of the total area of the Ca-containing AlON 13 set to 100%.

When the area ratio of the Ca-containing AlON crystal phase falls within such ranges, the volume resistivity of the grain boundary can be stably adjusted within an appropriate range as a conductive path of a JR electrostatic chuck.

The area ratio of the aluminum oxynitride containing calcium is calculated from an elemental mapping image obtained by analyzing a cross-section of the aluminum nitride sintered body with, for example, a field emission electron probe micro analyzer (FE-EPMA).

In the cross-section of the AlN sintered body 1, the Ca-containing AlON crystal phase 13 in an isolated state has any appropriate shape. Examples of the cross-sectional shape of the Ca-containing AlON crystal phase 13 include a circular shape, an elliptical shape, a polygonal shape, and other irregular shapes.

In the cross-section of the AlN sintered body 1, the average size (maximum dimension) of domains of the Ca-containing AlON crystal phase 13 is, for example, from 0.5 μm to 3.0 μm, preferably from 0.8 μm to 2.0 μm.

When the domain size of the Ca-containing AlON crystal phase falls within such ranges, the volume resistivity of the grain boundary can be more stably adjusted within an appropriate range as a conductive path of a JR electrostatic chuck.

The Ca-containing AlON crystal phase typically has a cubic crystal system. In one embodiment, Ca is present in AlON as a solid solution.

An a-axis length in the Ca-containing AlON is, for example, 7.9570 Å or more, preferably 7.9580 Å or more. Meanwhile, the a-axis length in the Ca-containing AlON is, for example, 7.9650 Å or less, preferably 7.9640 Å or less.

A unit cell volume in the Ca-containing AlON is, for example, from 503.70 Å³ to 505.00 Å³, preferably from 504.00 Å³ to 504.70 Å³.

In one embodiment, a portion of the grain boundary 12 except the Ca-containing AlON phase 13 (hereinafter referred to as “matrix portion” of the grain boundary 12) contains elements (Al and N) originating from AlN as main components. The matrix portion of the grain boundary 12 may further contain the above-mentioned metal elements excluding Al.

In one embodiment, the matrix portion of the grain boundary 12 further contains Ca as the metal element excluding Al. When the matrix portion of the grain boundary 12 contains Ca, the volume resistivity of the AlN sintered body in the temperature range of 250° C. or more can be adjusted within a range suitable for a JR electrostatic chuck.

### B-3. Physical Properties of Aluminum Nitride Sintered Body

The open porosity of such AlN sintered body 1 is, for example, 1.0% or less.

The open porosity of the aluminum nitride sintered body is measured in conformity with, for example, JIS-R1634.

The density of the AlN sintered body 1 is, for example, 3.0 g/cm³ or more, preferably 3.2 g/cm³ or more. Meanwhile, the upper limit of the density of the aluminum nitride sintered body 1 is typically 3.4 g/cm³.

The density of the aluminum nitride sintered body is measured in conformity with, for example, JIS-R1634.

The bending strength of the AlN sintered body 1 is, for example, 280 MPa or more, preferably 300 MPa or more, more preferably 310 MPa or more. Meanwhile, the upper limit of the bending strength of the AlN sintered body 1 is typically 450 MPa.

The bending strength of the aluminum nitride sintered body is measured in conformity with, for example, JIS-R1601.

The permittivity ε′ of the AlN sintered body 1 in the range of from 1 MHz to 13.56 MHz is, for example, from 8.0 to 9.0.

In addition, the dielectric loss tan δ of the AlN sintered body 1 in the range of from 1 MHz to 13.56 MHz is, for example, 1.0×10⁻³ or less. Meanwhile, the lower limit of the dielectric loss tan δ of the AlN sintered body 1 is typically 0.

The permittivity and dielectric loss of the aluminum nitride sintered body are measured by a both-ends short-circuited resonance method in conformity with, for example, JIS-R1627.

The heat conductivity of the AlN sintered body 1 at 300° C. is, for example, from 50 W/m·K to 100 W/m·K, preferably from 60 W/m·K to 80 W/m·K.

The heat conductivity of the aluminum nitride sintered body is measured in conformity with, for example, the flash method specified in JIS-R1611:2010.

### C. Method of Manufacturing Aluminum Nitride Sintered Body

Next, a method of manufacturing an aluminum nitride sintered body according to one embodiment is described.

In one embodiment, a method of manufacturing the aluminum nitride sintered body 1 includes: a molding step of preparing a molded body from an aluminum nitride raw material (hereinafter referred to as “AlN raw material”); and a firing step of firing the molded body.

### C-1. Molding Step

In the molding step, the AlN raw material is molded into a desired shape by any appropriate molding method to prepare a molded body.

The AlN raw material contains AlN as a main component. The AlN raw material typically contains, in addition to AlN, the above-mentioned metal elements excluding Al.

In one embodiment, the AlN raw material contains Ca as the metal element excluding Al. In addition, the AlN raw material may further contain oxygen. When the AlN raw material contains Ca and/or oxygen, the Ca-containing AlON can be stably formed at the grain boundary.

The AlN raw material typically has a powdery form. The average particle diameter D50 of the AlN raw material is, for example, from 1.0 μm to 1.5 μm.

Such AlN raw material may be granulated by any appropriate granulation method.

Examples of the molding method include press molding, sheet molding, and cold isostatic pressing (CIP), and doctor blade molding. Of those, press molding is preferred.

A pressure in the press molding is, for example, from 10 kgf/cm² to 500 kgf/cm², preferably from 100 kgf/cm² to 300 kgf/cm².

Thus, a molded body having a desired shape is prepared.

### C-2. Firing Step

Next, in the firing step, the molded body is typically fired under a vacuum or a non-oxidizing atmosphere. More specifically, the temperature is increased from normal temperature (23° C.) to a predetermined firing temperature, and the firing temperature is then maintained for a predetermined firing time.

The firing temperature is, for example, 1,900° C. or less, preferably 1,800° C. or less, more preferably 1,780° C. or less. Meanwhile, the firing temperature is, for example, 1,600° C. or more, preferably 1,650° C. or more, more preferably 1,700° C. or more.

The firing time is, for example, 10 hours or less, preferably 5 hours or less, more preferably 2 hours or less. Meanwhile, the lower limit of the firing time is typically 0.5 hour.

When the firing temperature and/or the firing time falls within such ranges, the average grain size of the crystal grains can be adjusted within the above-mentioned ranges, and the Ca-containing AlON can be present in an isolated state at the grain boundary.

An ambient pressure in the firing step is, for example, from 100 kPa to 900 kPa.

Examples of a firing method include hot pressing and hot isostatic pressing (HIP). Of those, hot pressing is preferred.

In the hot pressing, the molded body is typically arranged in a hot pressing die (e.g., a carbon jig), heated to the firing temperature as described above, and pressed under a predetermined pressure.

The pressure in the hot pressing is, for example, from 10 kgf/cm² to 500 kgf/cm², preferably from 100 kgf/cm² to 300 kgf/cm², more preferably from 150 kgf/cm² to 250 kgf/cm², still more preferably from 180 kgf/cm² to 220 kgf/cm².

When the pressure in the hot pressing falls within such ranges, the average grain size of the crystal grains can be stably adjusted within the above-mentioned ranges, and the Ca-containing AlON can be sufficiently present in an isolated state at the grain boundary.

In such firing step, AlN in the molded body is sintered, and the plurality of crystal grains and the grain boundary positioned between the crystal grains are formed. At this time, the Ca-containing AlON is formed so as to be present in an isolated state at the grain boundary. In one embodiment, Ca and oxygen in the molded body react with AlN to form the Ca-containing AlON.

In the manner described above, the AlN sintered body 1 is manufactured.

### D. Application of Aluminum Nitride Sintered Body

The AlN sintered body 1 is typically applied to a component (member for manufacturing a semiconductor) of a semiconductor manufacturing apparatus for manufacturing a semiconductor device. The member for manufacturing a semiconductor can be distributed independently and is an industrially applicable device. Examples of the member for manufacturing a semiconductor include a susceptor, a heater, an electrostatic chuck, a ceramic conductor, a feedthrough terminal, and a shower head.

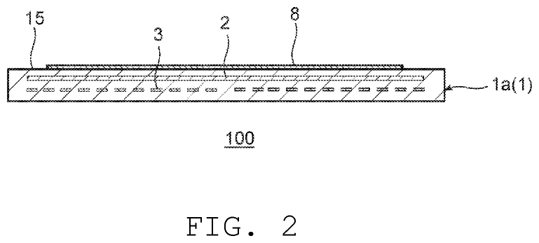

As illustrated in FIG. 2, in one embodiment, the AlN sintered body 1 is suitably applied to an electrostatic chuck 100.

The electrostatic chuck 100 typically includes a ceramic substrate 1a formed of the AlN sintered body 1, and an ESC electrode 2.

The ceramic substrate 1a functions as a wafer mounting plate. In the illustrated example, the ceramic substrate 1a has a mounting surface 15 on which a silicon wafer 8 can be mounted. The mounting surface 15 is one surface of the ceramic substrate 1a in its thickness direction.

The ceramic substrate 1a has any appropriate shape. In the illustrated example, the ceramic substrate 1a has a disc shape (see FIG. 1).

The thickness of the ceramic substrate 1a is, for example, from 10 mm to 50 mm.

The ESC electrode 2 is arranged inside the ceramic substrate 1a. In other words, the ESC electrode 2 is embedded in the ceramic substrate 1a.

The ESC electrode 2 is typically formed of a conductive material having a volume resistivity smaller than that of the AlN sintered body 1.

Examples of such conductive material include: metal carbide compounds such as tungsten carbide (WC); metal nitride compounds such as titanium nitride (TiN); and transition metals, such as molybdenum (Mo), tantalum (Ta), tungsten (W), platinum (Pt), rhenium (Re), and hafnium (Hf). The conductive materials may be used alone or in combination thereof.

The ESC electrode 2 has any appropriate shape. The ESC electrode 2 typically has a plate shape. In one embodiment, the ESC electrode 2 has a shape similar to the outer shape of the ceramic substrate 1a when viewed in the thickness direction of the ceramic substrate 1a. In the illustrated example, the center of the ESC electrode 2 and the center of the ceramic substrate 1a substantially coincide when viewed in the thickness direction of the ceramic substrate 1a.

The thickness (dimension of the ceramic substrate 1a in the thickness direction) of the ESC electrode 2 is, for example, from 10 μm to 50 μm, preferably from 20 μm to 30 μm.

In the illustrated example, the electrostatic chuck 100 includes one ESC electrode 2. The number of the ESC electrodes 2 is not particularly limited. The electrostatic chuck 100 may include a plurality of ESC electrodes 2.

The ceramic substrate 1a in which the ESC electrode 2 is embedded is manufactured by, for example, embedding the ESC electrode 2 (or a precursor of the ESC electrode) into a desired position of the molded body formed of the AlN raw material in the above-mentioned molding step, and firing the resultant in the above-mentioned firing step.

The electrostatic chuck 100 may further include a resistance heating element 3. The resistance heating element 3 is configured to generate heat when a voltage is applied thereto.

The resistance heating element 3 is arranged inside the ceramic substrate 1a. In other words, the resistance heating element 3 is embedded in the ceramic substrate 1a. In the illustrated example, the resistance heating element 3 is positioned on the side of the ESC electrode 2 opposite to the mounting surface 15 of the ceramic substrate 1a.

The resistance heating element 3 is formed of the above-mentioned conductive material.

The resistance heating element 3 has any appropriate shape. Examples of the shape of the resistance heating element 3 include a coil shape, a zigzag shape, and a mesh shape.

In such electrostatic chuck 100, the AlN sintered body 1 for forming the ceramic substrate 1a has a suitable volume resistivity, and hence in the temperature range of 250° C. or more, when a DC voltage is applied to the ESC electrode 2 under a state in which the silicon wafer 8 is mounted on the mounting surface 15, a suitable leakage current (e.g., from 0.5 mA to 1.5 mA) can be generated between the silicon wafer 8 and the ESC electrode 2. Accordingly, a JR force can be generated between the silicon wafer 8 and the ESC electrode 2, and hence the silicon wafer 8 can be stably chucked to the ceramic substrate 1a.

As a result, various types of treatment can be performed on the silicon wafer 8 with high precision to enable further miniaturization of a semiconductor device to be manufactured.

### EXAMPLES

The present disclosure is specifically described below by way of Examples and Comparative Examples. However, the present disclosure is by no means limited by these Examples. Measurement methods for characteristics are as described below.

(1) Measurement of Content Ratio of each of Constituent Elements in Aluminum Nitride Sintered Body

A central portion of an AlN sintered body manufactured in each of Example 1 and Comparative Example 1 was crushed to provide a first sample. In addition, a portion of the AlN sintered body having a pitch circle diameter (PCD) of from 285 mm to 335 mm was crushed to provide a second sample.

Further, a central portion of an AlN sintered body manufactured in each of Examples 2 and 3 and Comparative Example 2 was crushed to provide a first sample.

Next, a content ratio of each of constituent elements in each of the first samples and the second samples was measured in conformity with JIS-K0116 by inductively coupled plasma atomic emission spectroscopy (ICP-AES). The results are shown in Table 1 and Table 2.

### (2) Identification of Elemental Composition of Aluminum Nitride Sintered Body by FE-EPMA

A first test piece was cut out from the central portion of the AlN sintered body manufactured in each of Example 1 and Comparative Example 1. In addition, a second test piece was cut out from the portion of the AlN sintered body having a pitch circle diameter (PCD) of from 285 mm to 335 mm.

Further, a first test piece was cut out from the central portion of the AlN sintered body manufactured in each of Examples 2 and 3, and Comparative Example 2.

A cross-section of each of the first test pieces and the second test pieces along its thickness direction was mirror-polished by lapping to be used as a measurement surface.

Next, the polished surface was analyzed by FE-EPMA to provide elemental mapping images. Thus, the elemental composition of the AlN sintered body was identified. The results are shown in Table 1.

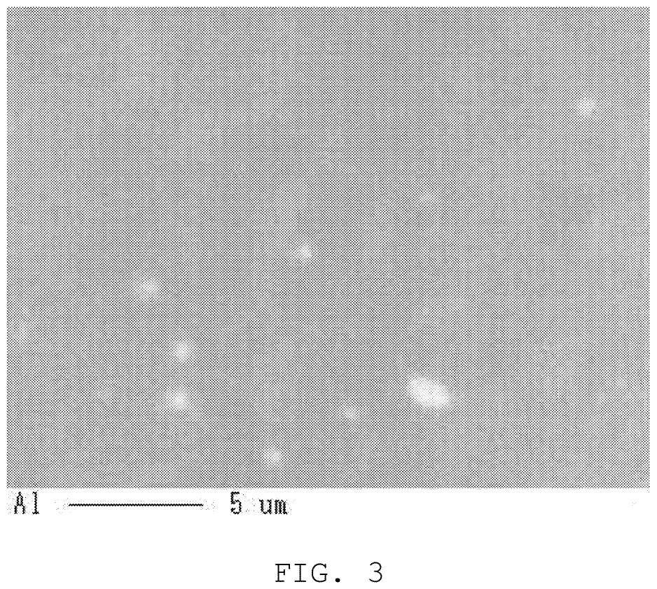

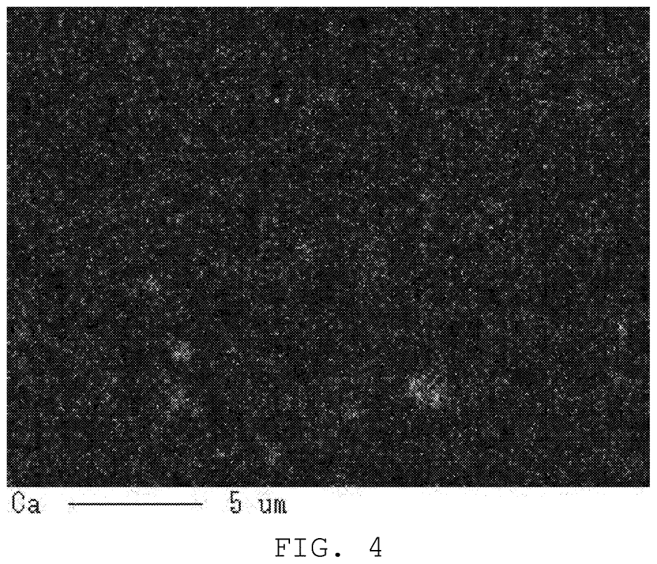

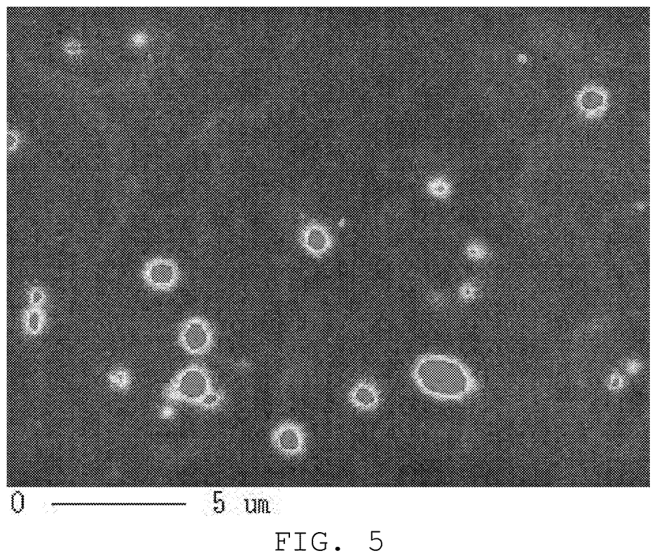

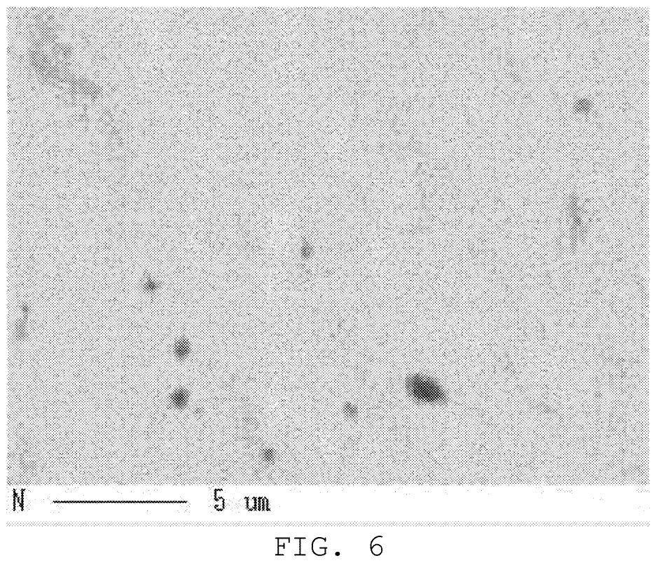

In addition, the mapping image of aluminum (Al) in the first test piece of Example 1 is shown in FIG. 3, the mapping image of calcium (Ca) in the first test piece of Example 1 is shown in FIG. 4, the mapping image of oxygen (O) in the first test piece of Example 1 is shown in FIG. 5, and the mapping image of nitrogen (N) in the first test piece of Example 1 is shown in FIG. 6.

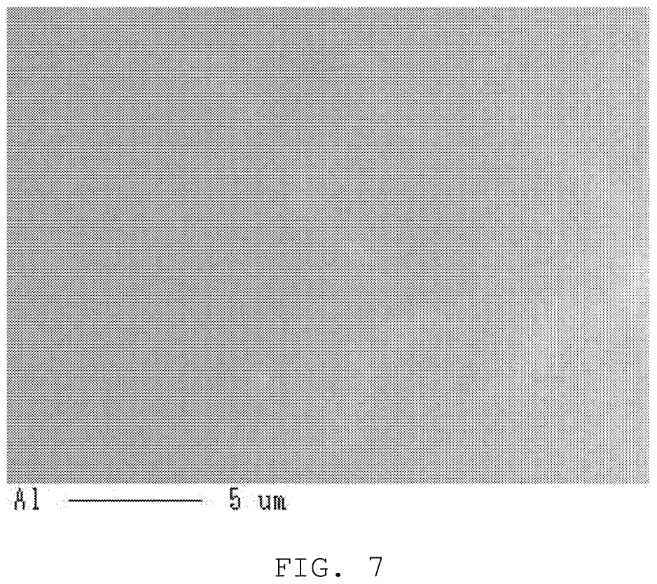

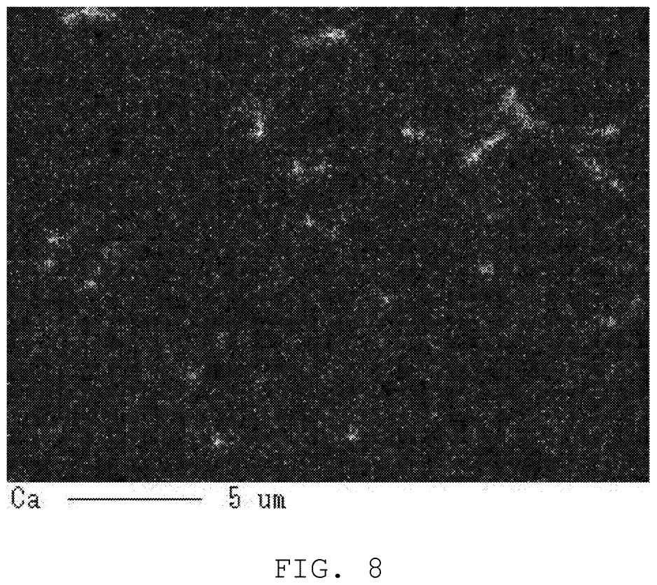

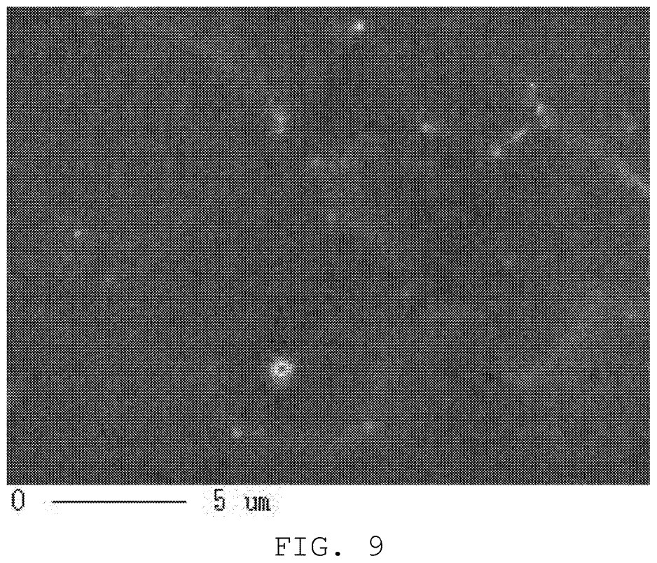

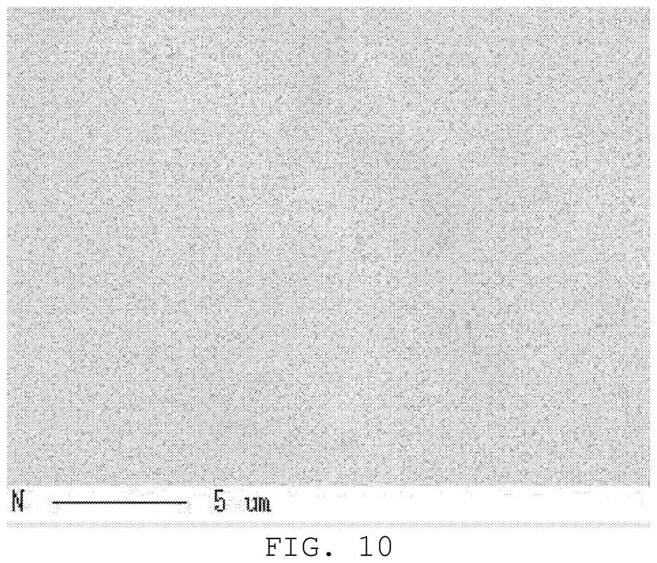

Further, the mapping image of aluminum (Al) in the first test piece of Comparative Example 1 is shown in FIG. 7, the mapping image of calcium (Ca) in the first test piece of Comparative Example 1 is shown in FIG. 8, the mapping image of oxygen (O) in the first test piece of Comparative Example 1 is shown in FIG. 9, and the mapping image of nitrogen (N) in the first test piece of Comparative Example 1 is shown in FIG. 10.

From those mapping images, it has been recognized that an aluminum oxynitride in which calcium is present as a solid solution (Ca-dissolved AlON) is present at a grain boundary in an isolated state in Examples. Meanwhile, no Ca-dissolved AlON was observed in Comparative Examples.

### (3) Calculation of Average Grain Size of Plurality of Crystal Grains and Standard Deviation Thereof

A first test piece and a second test piece were cut out from the AlN sintered body manufactured in each of Example 1 and Comparative Example 1 in the same manner as in “(2) Identification of Elemental Composition of Aluminum Nitride Sintered Body by FE-EPMA” described above.

Further, a first test piece was cut out from the AlN sintered body manufactured in each of Examples 2 and 3, and Comparative Example 2 in the same manner as described above.

Next, the average grain size of a plurality of crystal grains and the standard deviation thereof in each of the first test pieces and the second test pieces were calculated by: acquiring a backscattered electron image in a field of view at a magnification of 3,000 with a scanning electron microscope; and measuring the diameters of particles (N=40) corresponding to AlN in the backscattered electron image. The results are shown in Table 1 and Table 2.

### (4) Calculation of Lattice Constants of AlN

A first test piece and a second test piece were cut out from the AlN sintered body manufactured in each of Example 1 and Comparative Example 1 in the same manner as in “(2) Identification of Elemental Composition of Aluminum Nitride Sintered Body by FE-EPMA” described above.

Next, lattice constants of AlN in each of the first test pieces and the second test pieces were calculated by a whole powder pattern decomposition method (WPPD method) using software (TOPAS, manufactured by Bruker AXS). The a-axis length of AlN, the c-axis length of AlN, the ratio (c/a) of the c-axis length to the a-axis length, and the unit cell volume of AlN are shown in Table 1.

### (5) Measurement of Density of AlN Sintered Body

A first test piece and a second test piece were cut out from the AlN sintered body manufactured in each of Example 1 and Comparative Example 1 in the same manner as in “(2) Identification of Elemental Composition of Aluminum Nitride Sintered Body by FE-EPMA” described above.

Next, the density of each of the first test pieces and the second test pieces was calculated by the Archimedes method in conformity with JIS-R1634:1998. The results are shown in Table 1.

### (6) Calculation of Bending Strength of AlN Sintered Body and Standard Deviation Thereof.

A first test piece and a second test piece were cut out from the AlN sintered body manufactured in each of Example 1 and Comparative Example 1 in the same manner as in “(2) Identification of Elemental Composition of Aluminum Nitride Sintered Body by FE-EPMA” described above.

Next, the bending strength and standard deviation of each of the first test pieces and the second test pieces were calculated by measuring samples (N=10) for each test piece in conformity with JIS-R1601. The results are shown in Table 1.

### (7) Measurement of Volume Resistivity of Aluminum Nitride Sintered Body

A first test piece and a second test piece were cut out from the AlN sintered body manufactured in each of Example 1 and Comparative Example 1 in the same manner as in “(2) Identification of Elemental Composition of Aluminum Nitride Sintered Body by FE-EPMA” described above.

Further, a first test piece was cut out from the AlN sintered body manufactured in each of Examples 2 and 3 and Comparative Example 2 in the same manner as described above.

Next, the volume resistivity of each of the first test pieces and the second test pieces was measured at 300° C. or at room temperature (25° C.) in conformity with JIS-C2141. The applied voltage was +500 V. The results are shown in Table 1 and Table 2.

### (8) Measurement of Permittivity ε′ and Dielectric Loss tan δ of Aluminum Nitride Sintered Body

A first test piece and a second test piece were cut out from the AlN sintered body manufactured in each of Example 1 and Comparative Example 1 in the same manner as in “(2) Identification of Elemental Composition of Aluminum Nitride Sintered Body by FE-EPMA” described above.

Next, the permittivity and dielectric loss of each of the first test pieces and the second test pieces were measured by a capacitance method (two-terminal method). A frequency was 1 MHz or 13.56 MHz. The results are shown in Table 1.

### Example 1

A predetermined mold was filled with AlN raw material powder, followed by uniaxial pressing to provide a molded body having a disc shape. A pressure in the uniaxial pressing was 200 kgf/cm².

Next, the molded body was fired by hot pressing. More specifically, the molded body was first housed in a hot pressing die formed of graphite and set in a hot pressing furnace. After that, a pressure in the hot pressing furnace was increased to 0.25 MPa, and the molded body was pressed at a pressure of 200 kgf/cm² in its thickness direction. The molded body was fired in this state at 1,770° C. for 2 hours.

Thus, an AlN sintered body including a plurality of crystal grains containing AlN and a grain boundary positioned between adjacent crystal grains was manufactured. The AlN sintered body had a disc shape. The diameter of the AlN sintered body was 340 mm, and the thickness of the AlN sintered body was 25 mm.

### Examples 2 and 3

AlN sintered bodies were each manufactured in the same manner as in Example 1 except that the composition of the AlN raw material powder was adjusted so that the AlN sintered body to be manufactured had the composition shown in Table 2.

### Comparative Example 1

An AlN sintered body was manufactured in the same manner as in Example 1 except that: the temperature at which the molded body is fired was changed to 1,850° C.; and the firing time was changed to 4 hours.

### Comparative Example 2

An AlN sintered body was manufactured in the same manner as in Comparative Example 1 except that the composition of the AlN raw material powder was adjusted so that the AlN sintered body to be manufactured had the composition shown in Table 2.

TABLE 1

| | | | | Example 1 | | Comparative Example 1 | |
|---|---|---|---|---|---|---|---|
| | | | | Central | | Central | |
| | | | | portion | PCD285-335 | portion | PCD285-335 |
| No. | | | | (first | (second | (first | (second |
| Position within cut-out surface | | | | test piece) | test piece) | test piece) | test piece) |
| Composition | AlN | | [wt %] | 99.00(1) | 98.88(1) | 99.08(1) | 99.17(1) |
| of AlN | Al₅O₆N | | [wt %] | 1.00(0) | 1.12(0) | 0.92(0) | 0.83(0) |
| sintered | Metal | Ca | [ppm] | 200 | 200 | 200 | 200 |
| body | elements | Si | [ppm] | 14 | 14 | 15 | 15 |
| | excluding | Fe | [ppm] | 7 | 7 | 9 | 9 |
| | aluminum | Ti | [ppm] | 26 | 26 | 25 | 25 |
| | | Y | [ppm] | 2 | 2 | 2 | 2 |

| Crystal | Average grain | [μm] | 2.3 | 2.3 | 6.6 | 6.6 |
|---|---|---|---|---|---|---|
| grains | size | | | | | |
| | Standard | [μm] | 0.8 | 0.9 | 2.5 | 2.7 |
| | deviation σ of | | | | | |
| | average grain | | | | | |
| | size | | | | | |
| Lattice | a-Axis length | [Å] | 3.11205(1) | 3.11203(1) | 3.11183(1) | 3.11185(1) |
| constants of | c-Axis length | [Å] | 4.97916(2) | 4.97915(2) | 4.97944(2) | 4.97946(2) |
| AlN | c/a | [—] | 1.59996 | 1.59997 | 1.60016 | 1.60016 |
| | Unit cell volume | [Å³] | 41.7618(2) | 41.7613(2) | 41.7583(2) | 41.7590(2) |
| Volume | 300° C., +500 V | [Ω · cm] | 6.1 × 10⁹ | 7.7 × 10⁹ | 2.0 × 10¹⁰ | 3.1 × 10¹⁰ |
| resistivity | 25° C., +500 V | [Ω · cm] | 3.6 × 10¹⁴ | 5.5 × 10¹⁴ | 9.1 × 10¹⁴ | 1.0 × 10¹⁴ |
| Density | | [g/cm³] | 3.25 | 3.25 | 3.25 | 3.25 |
| Bending strength | | [MPa] | 334 | 334 | 302 | 308 |
| Standard deviation σ of | | [MPa] | 57 | 45 | 44 | 35 |
| bending strength | | | | | | |
| Permittivity | 1 MHz | [—] | 8.5 | 8.5 | 8.5 | 8.5 |
| ε′ | 13.56 MHz | [—] | 8.4 | 8.4 | 8.6 | 8.4 |
| Dielectric | 1 MHz | [×10⁻³] | 0.4 | 0.6 | 0.0 | 0.0 |
| loss tanδ | 13.56 MHz | [×10⁻³] | 0.0 | 0.0 | 0.0 | 0.0 |

*The numerical values in parentheses represent standard deviations.
The notation “96.9(1) wt %” means the range of 96.9 ± 0.1 wt %.

TABLE 2

| | | | | | | Comparative |
|---|---|---|---|---|---|---|
| No. | | | | Example 2 | Example 3 | Example 2 |
| Position within cut-out surface | | | | Central | Central | Central |
| | | | | portion | portion | portion |
| Composition | AlN | | [wt %] | 99.00 | 99.00 | 99.1 |
| of AlN | Al₅O₆N | | [wt %] | 1.00 | 1.00 | 0.9 |
| sintered | Metal | Ca | [ppm] | 150 | 150 | 250 |
| body | elements | Si | [ppm] | 20 | 20 | 20 |
| | excluding | Fe | [ppm] | 10 | 10 | 10 |
| | aluminum | Ti | [ppm] | 25 | 10 | 26 |
| | | Y | [ppm] | — | — | 2 |
| | | Mg | [ppm] | 3 | — | — |
| | | Sm | [ppm] | — | 5 | — |

| | | | | | |
|---|---|---|---|---|---|
| Crystal | Average grain size | [μm] | 2.1 | 2.8 | 6.0 |
| grains | Standard deviation σ | [μm] | 0.6 | 0.7 | 2.5 |
| | of average grain size | | | | |
| Volume | 300° C., +500 V | [Ω · cm] | 9.0 × 10⁹ | 8.0 × 10⁹ | 7.0 × 10¹⁰ |
| resistivity | | | | | |

### <Evaluation>

As shown in Table 1 and Table 2, it is found that in each AlN sintered body, even in the case where the average grain size of the crystal grains falls within the range of from 1.5 μm to 3.0 μm, when the content ratio of metal elements excluding Al is more than 30 ppm and 300 ppm or less, and Ca-dissolved AlON is present in an isolated state at the grain boundary, the volume resistivity of the AlN sintered body at 300° C. can be stably adjusted within a range (typically from 1.0×10⁹ Ω·cm to 5.0×10¹¹ Ω·cm, preferably from 1.0×10⁹ Ω·cm to 1.5×10¹⁰ Ω·cm) suitable for a JR electrostatic chuck.

The aluminum nitride sintered body according to the embodiment of the present disclosure can be typically used in a semiconductor manufacturing apparatus, and in particular, can be suitably used in an electrostatic chuck utilizing JR force.

What is claimed is:

1. An aluminum nitride sintered body, comprising:
a plurality of crystal grains each containing aluminum nitride; and
a grain boundary positioned between adjacent crystal grains among the plurality of crystal grains,
wherein an average grain size of the plurality of crystal grains is from 1.5 μm to 3.0 μm,
wherein the grain boundary includes a portion in which an aluminum oxynitride containing calcium is present in an isolated state, and
wherein a content ratio of metal elements excluding aluminum is more than 30 ppm and 300 ppm or less.

2. The aluminum nitride sintered body according to claim 1, wherein the content ratio of the metal elements excluding aluminum is more than 100 ppm.

3. The aluminum nitride sintered body according to claim 1, wherein a standard deviation of the average grain size of the plurality of crystal grains is 1.0 μm or less.

4. The aluminum nitride sintered body according to claim 1, wherein a volume resistivity of the aluminum nitride sintered body measured at 300° C. by applying a voltage of +500 V is from 5.0×10⁹ Ω·cm to 1.0×10¹⁰ Ω·cm.

5. The aluminum nitride sintered body according to claim 1, wherein the aluminum nitride sintered body has a bending strength of 300 MPa or more.
